(19) United States
(12) Patent Application Publication
(10) Pub. No.: US 2020/0335558 A1
(43) Pub. Date: Oct. 22, 2020

(54) ACTIVE MATRIX ORGANIC LIGHT EMITTING DIODE BACK PLATE, METHOD FOR PREPARING THE SAME, AND DISPLAY PANEL

(71) Applicant: BOE TECHNOLOGY GROUP CO., LTD., Beijing (CN)

(72) Inventors: Quanguo ZHOU, Beijing (CN); Lijia ZHOU, Beijing (CN); Zhidong WANG, Beijing (CN); Rongjian YAN, Beijing (CN); Jiuyang CHENG, Beijing (CN); Ronghua LAN, Beijing (CN); Qingguo YANG, Beijing (CN)

(21) Appl. No.: 16/622,831

(22) PCT Filed: Jul. 5, 2019
(86) PCT No.: PCT/CN2019/094793

§ 371 Date: Dec. 13, 2019

(30) Foreign Application Priority Data
Sep. 14, 2018 (CN) 201811074915.1

(51) Int. Cl. H01L 27/32; H01M 10/0525

(52) U.S. Cl. CPC H01L 27/3225; H01L 2227/323; H01M 10/0525; H01L 27/3258

(57) ABSTRACT

The present disclosure provides an active matrix organic light emitting diode back plate, a method for preparing the same, and a display panel. The active matrix organic light emitting diode back plate includes a thin film transistor and a thin film battery that are coplanar and arranged on the substrate, and a light emitting structure layer arranged on the thin film transistor and the thin film battery.

### CROSS-REFERENCE TO RELATED APPLICATIONS

The present disclosure is the U.S. national phase of PCT Application No. PCT/CN2019/094793 filed on Jul. 5, 2019, which claims a priority to Chinese Patent Application 201811074915.1 filed on Sep. 14, 2018, the disclosures of which are incorporated in their entirety by reference herein.

### TECHNICAL FIELD

The present disclosure relates to the field of display technology, in particular, to an active matrix organic light emitting diode back plate integrated with a thin film battery, a method for preparing the same, and a display panel.

### BACKGROUND

In recent years, active matrix organic light emitting diode (AMOLED) display panels have been widely used in various electronic devices due to their advantages, such as high reliability, high resolution, and high color gamut. With the development of technologies such as smart wearable devices and mobile applications, the light weight and long battery life of mobile devices have become an important development trend of flat panel display. At the same time, users propose new requirements for the screen size, brightness, color saturation and resolution of AMOLED display panels, so that the power consumption of the display panel increases accordingly. Therefore, how to improve the energy density of the battery and reduce the thickness of the battery has become an important problem to be solved in the field.

To this end, the related art proposes the concept of an all solid state thin film lithium battery. The all solid state thin film lithium battery replaces the liquid electrolyte in the conventional battery with a solid electrolyte, and thus has the advantages, such as high safety, light weight, charge and discharge at a high temperature, long life, fast charging, long battery life and flexibility. At present, when an all solid state thin film lithium battery is applied to an AMOLED display panel, the prior art generally uses a combined structure or a stacked structure. The combined structure is to separately prepare an AMOLED display panel and an all solid state thin film battery, and then to combine the them into one. The stacked structure is to arrange the all solid state thin film battery on the AMOLED back plate substrate or on the package layer in the preparation of the AMOLED display panel.

Due to the low system integration degree, the existing combined structure has a large thickness of the whole module. Since the existing stacked structure requires a thin film lithium battery and an array structure layer stacked sequentially in the preparation process, the number of patterning process is large, the preparation process is complicated and cumbersome, and the production cost is high.

### SUMMARY

Embodiments of the present disclosure provide an active matrix organic light emitting diode back plate including: a substrate; a thin film transistor and a thin film battery that are coplanar and located on the substrate; and a light emitting structure layer located on the thin film transistor and the thin film battery.

Optionally, a gate electrode of the thin film transistor and a positive current collector of the thin film battery are arranged in a same layer.

Optionally, a first electrode and a second electrode of the thin film transistor as well as a negative current collector of the thin film battery are arranged in a same layer.

Optionally, the thin film battery includes an all solid state thin film lithium battery.

Optionally, the thin film transistor includes: a polysilicon active layer on the substrate; a first insulating layer covering the polysilicon active layer; a gate electrode located on the first insulating layer; a second insulating layer covering the gate electrode, including a first via hole and a second via hole that expose the polysilicon active layer; a first electrode and a second electrode that are located on the second insulating layer, in which the first electrode and the second electrode are respectively connected to the polysilicon active layer through the first via hole and the second via hole; and a third insulating layer covering the first electrode and the second electrode, including a fourth via hole that exposes the first electrode.

Optionally, the thin film transistor includes: a gate electrode located on the substrate; a first insulating layer covering the gate electrode; an oxide active layer located on the first insulating layer; a first electrode and a second electrode that are located on the first insulating layer, in which one end of the first electrode is connected to the oxide active layer, one end of the second electrode is connected to the oxide active layer, and a conductive channel is formed between the first electrode and the second electrode; and a third insulating layer covering the first electrode and the second electrode, including a fourth via hole that exposes the first electrode.

Optionally, an etch stop layer is further arranged on the oxide active layer.

Optionally, the thin film battery includes a positive current collector, a positive electrode, an electrolyte, a negative electrode, and a negative current collector that are sequentially stacked.

An embodiment of the present disclosure further provides a display panel including the foregoing active matrix organic light emitting diode back plate.

An embodiment of the present disclosure also provides a method for preparing an active matrix organic light emitting diode back plate, including: forming a thin film transistor and a thin film battery that are coplanar on a substrate by a single preparation process; and forming a light emitting structure layer on the thin film transistor and the thin film battery.

Optionally, the step of forming the thin film transistor and the thin film battery that are coplanar on the substrate by the single preparation process includes: forming a gate electrode of the thin film transistor and a positive current collector of the thin film battery by the single patterning process.

Optionally, the step of forming the thin film transistor and the thin film battery that are coplanar on the substrate by the single preparation process includes: forming a first electrode and a second electrode of the thin film transistor as well as a negative current collector of the thin film battery by the single patterning process.

Optionally, the thin film battery includes an all solid state thin film lithium battery.

Optionally, the step of forming the thin film transistor and the thin film battery that are coplanar on the substrate by the single preparation process includes: forming a polysilicon active layer of the thin film transistor on the substrate; forming a gate electrode of the thin film transistor and a positive current collector of the thin film battery by the single patterning process; forming a positive electrode, an electrolyte, and a negative electrode of the thin film battery sequentially; and forming a first electrode and a second electrode of the thin film transistor as well as a negative current collector of the thin film battery by the single patterning process.

Optionally, the step of forming the gate electrode of the thin film transistor and the positive current collector of the thin film battery by the single patterning process includes: depositing a first insulating layer and a first metal thin film sequentially; and forming a first insulating layer covering the polysilicon active layer as well as a gate electrode of the thin film transistor located on the first insulating layer and a positive current collector of the thin film battery by a patterning process.

Optionally, the step of forming the positive electrode, the electrolyte and the negative electrode of the thin film battery sequentially includes: forming a second insulating layer covering the gate electrode and the positive current collector by a patterning process; forming a first via hole, a second via hole, and a third via hole on the second insulating layer, in which the first via hole and the second via hole are each located at a position where the polysilicon active layer is located, and the third via hole is located at a position where the positive current collector is located; and forming a positive electrode, an electrolyte, and a negative electrode of the thin film battery sequentially in the third via hole.

Optionally, the step of forming the first electrode and the second electrode of the thin film transistor as well as the negative current collector of the thin film battery by the single patterning process includes: depositing a second metal thin film; and forming a first electrode and a second electrode of the thin film transistor as well as a negative current collector of the thin film battery by the patterning process, in which the first electrode and the second electrode are respectively connected to the polysilicon active layer through the first via hole and the second via hole, and the negative current collector is formed on the negative electrode.

Optionally, the step of forming the thin film transistor and the thin film battery that are coplanar on the substrate by the single preparation process includes: forming a gate electrode of the thin film transistor and a positive current collector of the thin film battery by the single patterning process on the substrate; forming an oxide active layer of the thin film transistor; forming a positive electrode, an electrolyte, and a negative electrode of the thin film battery sequentially; and forming a first electrode and a second electrode of the thin film transistor as well as a negative current collector of the thin film battery by the single patterning process.

Optionally, the step of forming the gate electrode of the thin film transistor and the positive current collector of the thin film battery by the single patterning process on the substrate includes: depositing a first metal thin film on the substrate; and forming a gate electrode of the thin film transistor and a positive current collector of the thin film battery by a patterning process.

Optionally, the step of forming the oxide active layer of the thin film transistor includes: depositing a first insulating layer thin film and an active layer thin film sequentially; and forming a first insulating layer covering the gate electrode and the positive current collector as well as an oxide active layer located on the first insulating layer by a patterning process.

Optionally, the step of forming the positive electrode, the electrolyte and the negative electrode of the thin film battery sequentially includes: forming a third via hole on the first insulating layer by a patterning process, the third via hole being located at a position where the positive current collector is located; and forming a positive electrode, an electrolyte, and a negative electrode of the thin film battery sequentially in the third via hole.

Optionally, the step of forming the first electrode and the second electrode of the thin film transistor as well as the negative current collector of the thin film battery by the single patterning process includes: depositing a second metal thin film; and forming a first electrode and a second electrode of the thin film transistor as well as a negative current collector of the thin film battery by a patterning process, in which one end of the first electrode is connected to the oxide active layer, one end of the second electrode is connected to the oxide active layer, a conductive channel of the thin film transistor is formed between the first electrode and the second electrode, and the negative current collector is formed on the negative electrode.

### BRIEF DESCRIPTION OF THE DRAWINGS

The drawings described herein are intended to provide a further understanding of the technical solutions of the present disclosure, and constitute a part of this disclosure. They together with the embodiments of the present disclosure are intended to illustrate the technical solutions of the present disclosure, and do not constitute a limitation of the technical solutions of the present disclosure. The shapes and sizes of the various components in the drawings do not reflect true proportions, but are merely intended to illustrate the present disclosure.

FIG. 1 is a schematic view showing a structure of an active matrix organic light emitting diode back plate according to an embodiment of the present disclosure;

FIG. 2 is a schematic view showing a structure of an AMOLED back plate according to an embodiment of the present disclosure;

FIG. 3 is a schematic view showing forming a pattern of an active layer according to an embodiment of the present disclosure;

FIG. 4 is a schematic view showing forming patterns of a gate electrode and a positive current collector according to an embodiment of the present disclosure;

FIG. 5 is a schematic view showing forming a pattern of a second insulating layer with a via hole according to an embodiment of the present disclosure;

FIG. 6 is a schematic view showing forming patterns of a positive electrode, an electrolyte, and a negative electrode according to an embodiment of the present disclosure;

FIG. 7 is a schematic view showing forming patterns of a first electrode, a second electrode, and a negative current collector according to an embodiment of the present disclosure;

FIG. 8 is a schematic view showing forming a pattern of a third insulating layer with a via hole according to an embodiment of the present disclosure;

FIG. 9 is a schematic view showing forming a pattern of an anode according to an embodiment of the present disclosure;

FIG. 10 is a schematic view showing forming a pattern of a fourth insulating layer with a via hole according to an embodiment of the present disclosure;

FIG. 11 is a schematic view showing a structure of an AMOLED back plate according to another embodiment of the present disclosure;

FIG. 12 is a schematic view showing forming patterns of a gate electrode and a positive current collector according to another embodiment of the present disclosure;

FIG. 13 is a schematic view showing forming a pattern of an active layer according to another embodiment of the present disclosure;

FIG. 14 is a schematic view showing forming a pattern of a via hole on a first insulating layer according to another embodiment of the present disclosure;

FIG. 15 is a schematic view showing forming patterns of a positive electrode, an electrolyte, and a negative electrode according to another embodiment of the present disclosure;

FIG. 16 is a schematic view showing forming patterns of a first electrode, a second electrode, and a negative current collector according to another embodiment of the present disclosure;

FIG. 17 is a schematic view showing forming a pattern of a third insulating layer with a via hole according to another embodiment of the present disclosure;

FIG. 18 is a schematic view showing a structure of an AMOLED back plate according to a yet embodiment of the present disclosure;

FIG. 19 is a schematic view showing a structure of an AMOLED back plate according to another embodiment of the present disclosure;

FIG. 20 is a flow chart showing a method for preparing an active matrix organic light emitting diode back plate according to an embodiment of the present disclosure.

### DETAILED DESCRIPTION

The detailed description of the present disclosure will be further described in detail below with reference to the drawings and examples. The following examples are used to illustrate the disclosure, but are not intended to limit the scope of the disclosure. It should be noted that the embodiments in the disclosure and the features in the embodiments can be arbitrarily combined with each other, as long as they contradict each other.

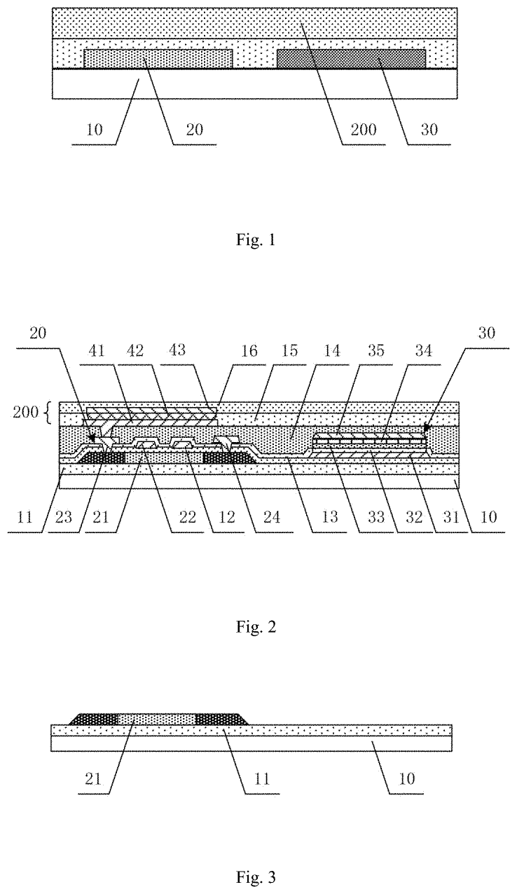

An embodiment of the present disclosure provide an active matrix organic light emitting diode back plate integrated with a thin film battery to overcome the defects of the existing module, such as a large thickness of the whole module and a high production cost. FIG. 1 is a schematic view showing a structure of an active matrix organic light emitting diode back plate according to an embodiment of the present disclosure. As shown in FIG. 1, in the embodiment of the present disclosure, the main structure of the active matrix organic light emitting diode back plate includes: a substrate 10, a thin film transistor 20 and a thin film battery 30 that are coplanar and arranged on the substrate 10, and a light emitting structure layer 200 arranged on the thin film transistor 20 and the thin film battery 30.

In the context of the present disclosure, two elements that are coplanar means that the two elements are juxtaposed at substantially the same height, the two elements being arranged on the same plane parallel to the substrate, or the two elements being sandwiched between the same two layers.

In an embodiment of the present disclosure, the thin film transistor includes a gate electrode, an active layer, a first electrode, and a second electrode; and the thin film battery includes a positive current collector, a positive electrode, an electrolyte, a negative electrode, and a negative current collector. A thin film transistors and a thin film battery that are coplanar can be formed by a single preparation process. Among them, forming the thin film transistor and the thin film battery by a single preparation process means that the gate electrode of the thin film transistor and the positive electrode current collector of the thin film battery are arranged in the same layer, and the first electrode and the second electrode of the thin film transistor as well as the negative current collector of the thin film battery layer are arranged in the same layer. In the context of the present disclosure, the two elements being “arranged in the same layer” mean that the two elements are formed of the same material by a single patterning process.

By constructing a thin film transistor and a thin film battery that are coplanar, the active matrix organic light emitting diode back plate provided by the embodiments of the present disclosure maximizes the integration degree, effectively reduces the overall module thickness, forms a thin film transistor and a thin film battery through a single preparation process, minimizes the number of the patterning process, simplifies the preparation process, and effectively reduces production costs.

The technical solutions of the embodiments of the present disclosure will be described in detail below by means of specific embodiments.

FIG. 2 is a schematic view showing a structure of an AMOLED back plate according to an embodiment of the present disclosure. In recent years, display technology has been rapidly developed, and thin film transistor (TFT) technology has evolved from the original amorphous silicon (a-Si) thin film transistor to the low temperature poly-silicon (LTPS) thin film transistor. LTPS thin film transistors have many advantages, and their electron mobility can reach 200 cm²/V□sec or more, which not only can effectively reduce the area of thin film transistors and increase the aperture ratio, but also reduce the overall power consumption while increasing the display brightness. In addition, the higher electron mobility can integrate part of the driving circuit on the substrate, reduce the driving integrated circuit IC, greatly improve the reliability of the liquid crystal display panel, and greatly reduce the production cost. Therefore, LTPS thin film transistors have gradually become a research hotspot in the field of display technology. In this embodiment, the AMOLED back plate uses LTPS technology, and the pixel driving circuit includes a plurality of thin film transistors and capacitors, e.g., a 2T1C pixel driving circuit having two thin film transistors and a capacitor, in which one of the two thin film transistors is a switching thin film transistor (Switching TFT) and the other of the two thin film transistors is a driving thin film transistor (Driving TFT). In order to clearly illustrate the relationship between the thin film transistor and the thin film battery, only one thin film transistor is shown in FIG. 2.

As shown in FIG. 2, in the embodiment, the main structure of the AMOLED back plate includes: a thin film transistor 20 and a thin film battery 30 that are coplanar and arranged on the substrate 10, and a light emitting structure layer 200 arranged on the thin film transistor 20 and the thin film battery 30. The thin film transistor 20 is a top gate structure, and includes an active layer 21, a gate electrode 22, a first electrode 23, and a second electrode 24. The thin film battery 30 includes a positive current collector 31, a positive electrode 32, an electrolyte 33, a negative electrode 34 and a negative current collector 35 that are sequentially stacked.

The structure of the AMOLED back plate of this embodiment will be described in detail below from the perspectives of a thin film transistor and a thin film battery.

As shown in FIG. 2, the thin film transistor 20 of the AMOLED back plate of the embodiment includes: a buffer layer 11 covering the substrate 10 and an active layer 21 arranged on the buffer layer 11, in which the active layer 21 is a polysilicon active layer, and includes a channel region and a doped region located on both sides of the channel region; a first insulating layer 12 covering the active layer 21; a gate electrode 22 arranged on the first insulating layer 12, in which the gate electrode 22 and the positive electrode current collector 31 of the thin film battery 30 are arranged in the same layer and formed by a single patterning process; a second insulating layer 13 covering the gate electrode 22, on which a first via hole and a second via hole respectively exposing the doped region of the active layer 21 are provided; a first electrode 23 and a second electrode 24 arranged on the second insulating layer 13, in which the first electrode 23 is connected to the doped region on one side of the active layer 21 through the first via hole, the second electrode 24 is connected to the doped region on the other side of the active layer 21 through the second via hole, and the first electrode 23 and the second electrode 24 as well as the negative current collector 35 of the thin film battery 30 are arranged in the same layer and formed by a single patterning process; and a third insulating layer 14 covering the first electrode 23 and the second electrode 24, on which a fourth via hole exposing the first electrode 23 is provided.

In this embodiment, the active layer 21 is made of polysilicon, the doped regions on both sides of the active layer 21 being P-type doped polysilicon; the gate electrode 22 is a double gate structure, in which the two gate electrodes 22 are juxtaposed at a position corresponding to the channel region of the active layer 21; the first electrode 23 is a drain electrode and connected to the doped region on one side of the active layer 21, and the second electrode 24 is a source electrode and connected to the doped region on the other side of the active layer 21. In actual implementation, the buffer layer is not necessary, and may be provided according to the process requirements. The gate electrode may also adopt a single gate structure, and the doped region may also adopt N-doped polysilicon. The first electrode and the second electrode may also be the source electrode and the drain electrode, respectively.

As shown in FIG. 2, the thin film battery 30 of the AMOLED back plate of the present embodiment includes: a buffer layer 11 and a first insulating layer 12 that sequentially cover the substrate 10; a positive current collector 31 arranged on the first insulating layer 12, in which a positive current collector 31 and the gate electrode 22 of the thin film transistor 20 are arranged in the same layer and formed by a single patterning process; a second insulating layer 13 covering the positive current collector 31, on which a third via hole exposing the positive current collector 31 is provided; a positive electrode 32 arranged on the positive current collector 31 in the third via hole; an electrolyte 33 arranged on the positive electrode 32; a negative electrode 34 arranged on the electrolyte 33; a negative current collector 35 arranged on the negative electrode 34, in which a negative current collector 35 as well as the first electrode 23 and the second electrode 24 of the thin film transistor 20 are arranged in the same layer and formed by a single patterning process; and a third insulating layer 14 covering the negative current collector 35.

Generally, according to the type of electrolytes thereof, a thin film battery can be basically classified into three major categories: a liquid electrolyte thin film battery, a solid electrolyte thin film battery, and a gel electrolyte thin film battery. The all solid state thin film battery has its inherent advantages, that is, it does not dry or leak, and its preparation process can be compatible with the array structure process in the back plate. The temperature of the AMOLED back plate is increased during operation, which is more favorable for the all solid state thin film battery to achieve better performance. Therefore, the thin film battery 30 of the present embodiment is preferably an all solid state thin film lithium battery. In this embodiment, the respective structures of the thin film battery 30 are stacked. The positive current collector may be made of a material, such as molybdenum Mo or aluminum Al, and the negative current collector may be made of a material, such as molybdenum Mo or copper Cu. The positive electrode may be made of lithium cobalt oxide LCO or lithium manganate LMO, lithium nickel manganese oxide LNMO, lithium nickel cobalt aluminate NCA, nickel cobalt manganese NCM, copper sulfide CuS and other materials; and the negative electrode can be made of tin oxide SnO₂, lithium metal, graphite, lithium-containing alloy or lithium-containing compound and other materials. The solid electrolyte can be of lithium phosphide-nitrogen type LiPON, perovskite type LLTO, sulfide type, thio-LISICON electrolyte type Thio-LiSiCON, lithium aluminum phosphate type LATP, garnet type LLZO, lithium germanium phosphide type LGSP or lithium phosphorus sulfur type LPS, etc.

As shown in FIG. 2, the light emitting structure layer 200 of the AMOLED back plate of the present embodiment includes: an anode 41 arranged on the third insulating layer 14, in which the anode 41 is connected to the first electrode 23 of the thin film transistor 20 through the fourth via hole; a fourth insulating layer 15 covering the anode 41, on which a fifth via hole exposing the anode 41 is provided; a light emitting layer 42 arranged on the anode 41 in the fifth via hole; a cathode 43 arranged on the light emitting layer 42; and a package layer 16 covering the above structure.

As shown in FIG. 2, the AMOLED back plate of the present embodiment includes: a substrate 10; a buffer layer 11 covering the substrate 10; an active layer 21 arranged on the buffer layer 11, in which the active layer 21 is a polysilicon active layer, including a channel region and a doped region located on both sides of the channel region; a first insulating layer 12 covering the active layer 21; a gate electrode 22 of the thin film transistor and a positive current collector 31 of the thin film battery that are formed on the first insulating layer 12 by a single patterning process; a second insulating layer 13 covering the gate electrode 22 and the positive current collector 31, on which a first via hole and a second via hole exposing a doped region of the active layer 21 are provided and a third via hole exposing the positive current collector 31; a positive electrode 32, an electrolyte 33 and a negative electrode 34 arranged in the third via hole; a first electrode 23 and a second electrode 24 of the thin film transistor arranged on the second insulating layer 13, and a negative current collector 35 of the thin film battery arranged on the negative electrode 34, in which the first electrode 23 and the second electrode 24 as well as the negative current collector 35 are formed by a single patterning process, the first electrode 23 is connected to the doped regions on one side of the active layer 21 through the first via hole, the second electrode 24 is connected to the doped region on the other side of the active layer 21 through the second via hole, and the negative current collector 35 is arranged on the negative electrode 34; a third insulating layer 14 covering the first electrode 23, the second electrode 24, and the negative current collector 35, on which a fourth via hole exposing the first electrode 23 is provided; an anode 41 arranged on the third insulating layer 14, in which the anode 41 is connected to the first electrode 23 of the thin film transistor 20 through the fourth via hole; a fourth insulating layer 15 covering the anode 41, on which a fifth via hole exposing the anode 41 is provided; a light emitting layer 42 arranged on the anode 41 in the fifth via hole; a cathode 43 arranged on the light-emitting layer 42; and a package layer 16 covering the foregoing structure.

The technical solution of the embodiment of the present disclosure is further illustrated by the preparation process of the active matrix organic light emitting diode back plate. The “patterning process” in the embodiment of the present disclosure includes many steps such as depositing a film layer, coating a photoresist, exposing a mask, development, etching, stripping a photoresist, etc., and is a mature preparation process in the related art. The deposition may be carried out by a known process such as sputtering, evaporation, chemical vapor deposition, etc. The coating may be carried out by a known coating process. The etching may be carried out by a known method, which is not specifically limited herein.

First, an pattern of the active layer is formed. The forming the active layer pattern includes: sequentially depositing a buffer layer thin film and a polysilicon thin film on the substrate, coating a layer of photoresist on the polysilicon thin film, stepwise exposing and developing the photoresist by using a halftone mask or a gray tone mask, forming an unexposed region at a position of the channel region of the active layer with a photoresist of a first thickness, forming a partially exposed region at a position of the doped region of the active layer with a photoresist of a second thickness less than the first thickness, forming a fully exposed region at other locations without photoresist, and exposing the polysilicon thin film. The polysilicon thin film of the fully exposed region is etched by the first etching, to form a pattern of the active layer on the buffer layer thin film. Subsequently, the photoresist is removed to the second thickness as a whole by a photoresist ashing process, that is, the photoresist in the partially exposed region is removed to expose the polysilicon thin film of the partially exposed region. Then, the exposed polysilicon thin film is P+doped to form a doped region of the active layer 21, and the remaining photoresist is stripped to form a buffer layer 11 and a pattern of the active layer 21 of the thin film transistor on the substrate 10. The active layer 21 includes an undoped region in the middle (channel region) and doped regions on both sides of the channel region, as shown in FIG. 3.

In this embodiment, the polycrystalline silicon p-Si thin film may be formed by directly depositing a polysilicon material; or the amorphous thin film may be processed to form a polycrystalline silicon thin film by laser irradiating a deposited amorphous silicon a-Si thin film. For doped regions, high doses of boron may be used, or other ions may be used for implantation. The substrate may be a rigid substrate or a flexible substrate, in which the rigid substrate may be made of glass, plastic, polymer, metal sheet, silicon wafer, quartz, ceramic, mica, etc.; and the flexible substrate may be made of materials, such as polyimide (PI), polyethylene terephthalate (PET), zirconia or alumina. In actual implementation, the buffer layer is not necessary, and the buffer layer may or may not be provided according to actual needs. The buffer layer is used to prevent metal ions in the substrate from diffusing to the active layer, thereby preventing effects on characteristics such as threshold voltage and leakage current. A suitable buffer layer can improve the quality of the back interface of the polysilicon layer, prevent leakage current at the back interface of the polysilicon layer, and further reduce heat conduction and slow down the cooling rate of the silicon heated by the laser. In this embodiment, the buffer layer may be silicon nitride SiNₓ, silicon oxide SiOₓ or silicon oxynitride SiOₓNₓ; and may be a single layer or a composite thin film of SiNₓ/SiOₓ, SiNₓ/SiOₓNₓ, SiOₓNₓ/SiOₓ or SiNₓ/SiOₓ/SiOₓNₓ. In actual implementation, it is not necessary to dope the active layer to form the doped regions on both sides. When doping is not required, an pattern of the active layer is formed by patterning the polysilicon thin film using a monotone mask.

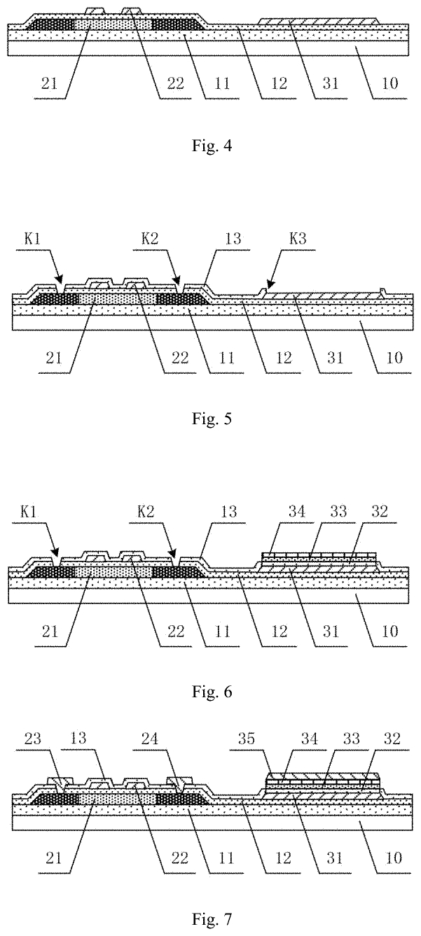

Subsequently, patterns of the gate electrode and the positive current collector are formed. The step of forming patterns of the gate electrode and the positive current collector includes: sequentially depositing a first insulating layer thin film and a first metal thin film on the substrate on which the foregoing patterns have been formed, coating a photoresist on the first metal thin film, exposing and developing the photoresist by using a monotone mask, in which an unexposed region is formed at the position of patterns of the gate electrode and the positive current collector and the photoresist is reserved, and a completely exposed region is formed at other positions and no photoresist is reserved, thereby exposing the first metal thin film; etching the first metal thin film exposed by the exposed region and stripping the remaining photoresist, and forming a pattern of the gate electrode 22 of the thin film transistor and a pattern of the positive current collector 31 of the thin film battery on the first insulating layer 12, as shown in FIG. 4. The gate electrode 22 has a double gate structure, and the two gate electrodes 22 are juxtaposed at a position corresponding to the channel region of the active layer 21. The first insulating layer may be SiNₓ, SiOₓ or SiOₓNₓ, may be a single layer or a multilayer composite thin film, also referred to as a gate insulating (GI) layer. The first metal thin film may be made of a material, such as molybdenum Mo or aluminum Al. In this process, the gate electrode of the thin film transistor and the positive current collector of the thin film battery are arranged in the same layer, and are formed by a single patterning process.

Subsequently, a second insulating layer pattern with via holes is formed. The step of forming the second insulating layer pattern with via holes includes: depositing a second insulating layer thin film on the substrate on which the foregoing patterns have been formed, coating a layer of photoresist on the second insulating layer thin film, and exposing and developing the photoresist by using a monotone mask, forming a fully exposed region at a position of the doped region of the active layer 21 and at the position of the pattern of the positive current collector 31, removing the photoresist, forming an unexposed region at other positions, and retaining the photoresist; etching the fully exposed region and stripping the remaining photoresist to form a pattern of the second insulating layer 13 provided with a first via hole K1, a second via hole K2 and a third via hole K3, in which the first via hole K1 is located at the position of the doped region on one side of the active layer 21, the second via hole K2 is located at the position of the doped region on the other side of the active layer 21, the second insulating layer 13 and the first insulating layer 12 in the first via hole K1 and the second via hole K2 being etched to expose the surface of the doped region of the active layer 21; the third via hole K3 is located at the position of the positive current collector 31, the second insulating layer thin film in the third via hole K3 being etched to expose the surface of the positive current collector 31, as shown in FIG. 5. The second insulating layer may be made of SiNx, SiOₓ or SiOₓNₓ, and may be a single layer or a composite thin film of SiNₓ/SiOₓ, SiNₓ/SiOₓNₓ, SiOₓNₓ/SiOₓ or SiNₓ/SiOₓ/SiOₓNₓ, also referred to as an interlayer dielectric (ILD) layer.

Subsequently, patterns of the positive electrode, the electrolyte, and the negative electrode pattern are formed. The step of forming the patterns of the positive electrode, the electrolyte, and the negative electrode includes: sequentially forming patterns of the positive electrode 32, the electrolyte 33, and the negative electrode 34 of the thin film battery in the third via hole K3 by a shadow mask process, in which the positive electrode 32 is formed on the positive current collector 31 and connected to the positive current collector 31, the electrolyte 33 is formed on the positive electrode 32, and the negative electrode 34 is formed on the electrolyte 33, as shown in FIG. 6. The positive electrode may be made of materials, such as lithium cobaltate LCO, lithium manganate LMO, lithium nickel manganate LNMO, lithium nickel cobalt aluminate NCA, nickel cobalt manganese NCM, and copper sulfide CuS. The electrolyte may be of lithium phosphide-nitrogen type LiPON, perovskite type LLTO, sulfide type, thio-LISICON electrolyte type thio-LiSiCON, lithium titanium aluminum phosphate type LATP, garnet type LLZO, lithium germanium sulfur phosphide type LGSP or lithium phosphorus sulfur type LPS, and other materials. The negative electrode film may be made of a material, such as tin oxide SnO₂, lithium metal, graphite, a lithium-containing alloy, or a lithium-containing compound. The present embodiment uses the shadow mask process to form the positive electrode, the electrolyte and the negative electrode in the same manner as in the prior art, which is well known to a person skilled in the art and will not be described herein.

Subsequently, patterns of the first electrode, the second electrode, and the negative current collector are formed. The step of forming patterns of the first electrode, the second electrode, and the negative current collector includes: depositing a second metal thin film on the substrate on which the foregoing patterns have been formed, patterning the second metal thin film by a patterning process, forming patterns of the first electrode 23 and the second electrode 24 of the thin film transistor on the second insulating layer 13, forming a pattern of the negative current collector 35 of the thin film battery on the negative electrode 34, in which the first electrode 23 is connected to the doped region on the side of the active layer 21 through the first via hole K1, the second electrode 24 is connected to the doped region on the other side of the active layer 21 through the second via hole K2, and the negative current collector 35 is arranged on the negative electrode 34, as shown in FIG. 7. The second metal thin film may be made of a material, such as molybdenum Mo or copper Cu. In this embodiment, the first electrode 23 is a drain electrode, and the second electrode 24 is a source electrode. In this process, the first electrode and the second electrode of the thin film transistor as well as the negative current collector of the thin film battery are arranged in the same layer, and formed by a single patterning process.

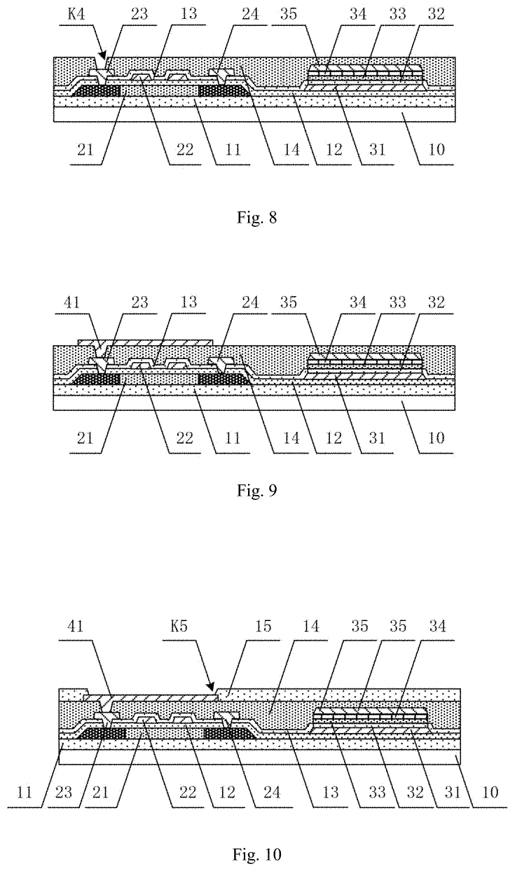

Subsequently, a pattern of the third insulating layer with via holes is formed. The step of forming the third insulating layer pattern with via holes includes: coating a third insulating layer thin film on the substrate on which the foregoing patterns have been formed, and forming a pattern of the third insulating layer 14 with the fourth via hole K4 through masking, exposing and developing, in which the fourth via hole K4 is located at the position of the first electrode 23, and etching the third insulating layer 14 in the fourth via hole K4 to expose the surface of the first electrode 23, as shown in FIG. 8. The third insulating layer may be made of a resin material, also referred to as a planarization (PLN) layer, to function as a planarization.

Subsequently, a pattern of the anode is formed. The step of forming the pattern of the anode includes: depositing a transparent conductive thin film on the substrate on which the foregoing patterns have been formed, patterning the transparent conductive thin film by a patterning process, and forming a pattern of the anode 41 of the light emitting structure layer on the third insulating layer 14, in which the anode 41 is connected to the first electrode 23 of the thin film transistor through the fourth via hole K4, as shown in FIG. 9. The transparent conductive thin film may be made of indium tin oxide ITO or indium zinc oxide IZO.

Subsequently, a pattern of the fourth insulating layer with via holes is formed. The step of forming the pattern of the fourth insulating layer with the via holes includes: depositing a fourth insulating layer thin film on the substrate on which the foregoing patterns have been formed, patterning the fourth insulating layer thin film by a patterning process, forming a pattern of the fourth insulating layer 15 with the fifth via hole K5, in which the fifth via hole K5 is located at the position of the anode 41, and etching the fourth insulating layer 15 in the fifth via hole K5 to expose the surface of the anode 41, as shown in FIG. 10. The fourth insulating layer may be made of polyimide or acrylic or polyethylene terephthalate, also referred to as a pixel definition layer (PDL). The pixel definition layer is used to define a plurality of pixel regions, to expose the light emitting region.

Subsequently, patterns of the light emitting layer, the cathode and the package layer are formed. The step of forming patterns of the light emitting layer, the cathode and the package layer includes: forming patterns of the light emitting layer 42 and the cathode 43 sequentially on the substrate on which the foregoing patterns have been formed in a vapor deposition manner, in which the light emitting layer 42 is formed on the anode 41 in the fifth via hole K5 to connect the light emitting layer 42 to the anode 41, and the cathode 43 is arranged on the light emitting layer 42. Finally, the package layer 16 is formed on the substrate on which the foregoing patterns have been formed by coating, as shown in FIG. 2.

As can be seen from the foregoing description, in the present embodiment, the gate electrode of the thin film transistor and the positive current collector of the thin film battery are arranged in the same layer and formed by a single patterning process, and the first electrode and the second electrode of the thin film transistor as well as the negative current collector of the thin film battery are arranged in the same layer and formed by a single patterning process, thus a simultaneous preparation of a thin film transistor and thin film battery that are coplanar can be achieved thereby. Since the thin film transistor and the thin film battery are coplanar, the active matrix organic light emitting diode back plate of the embodiment of the present disclosure maximizes integration and reduces the overall module thickness, as compared with the existing combined structure. Since the thin film transistor and the thin film battery are simultaneously prepared, the active matrix organic light emitting diode back plate of the embodiment of the present disclosure significantly reduces the number of patterning process, simplifies the preparation process, and reduces the production cost, as compared with the existing stacked structure.

It should be noted that the foregoing description is merely an example of preparing an AMOLED back plate, and the disclosure is not specifically limited herein. In actual implementation, the preparation process can be adjusted according to actual needs. For example, in the preparation process of FIG. 3, the doped region may also form a heavily drain doping (HDD) region and a lightly drain doping (LDD) region. For example, in the preparation process of FIG. 5, a third via hole may be formed first; patterns of the positive electrode, the electrolyte and the negative electrode are formed in the third via hole, and then patterns of the first via hole and the second via are formed by a patterning process. For example, the active matrix OLED back plate may also be provided with a shielding metal layer or the like.

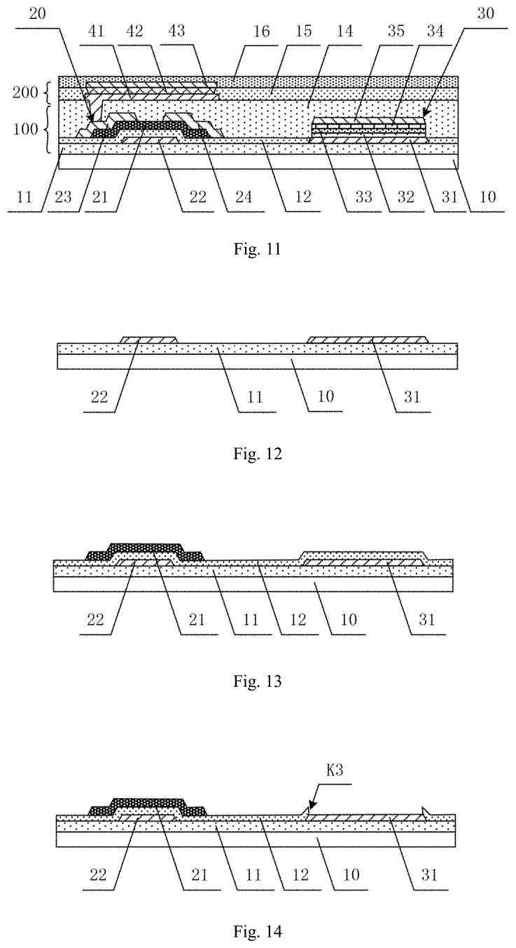

FIG. 11 is a schematic view showing a structure of an AMOLED back plate according to another embodiment of the present disclosure. In recent years, oxide thin film transistors have been rapidly developed. Oxide, such as indium gallium zinc oxide (IGZO) or indium tin zinc oxide (ITZO), is used as an active layer, and its carrier mobility is 20 to 30 times that of amorphous silicon. It has the characteristics of large mobility, high on-state current, better switching characteristics and better uniformity, which can greatly improve the charge and discharge rate of the thin film transistor to the pixel electrode, improve the response speed of the pixel, achieve a faster refresh rate, and may be suitable for applications requiring fast response and high current, such as high-frequency, high-resolution, large-size displays, and organic light emitting displays. In this embodiment, the AMOLED back plate adopts an oxide thin film transistor technology, and the pixel driving circuit includes a plurality of thin film transistors and capacitors, while only one thin film transistor is shown in FIG. 11.

As shown in FIG. 11, in the embodiment, the main structure of the AMOLED back plate includes: a thin film transistor 20 and a thin film battery 30 that are coplanar and arranged on the substrate 10, and a light emitting structure layer 200 arranged on the thin film transistor 20 and the thin film battery 30. The thin film transistor 20 is a bottom gate structure, including a gate electrode 22, an active layer 21, a first electrode 23, and a second electrode 24. The thin film battery 30 is an all solid state thin film lithium battery, including a positive current collector 31, a positive electrode 32, an electrolyte 33, a negative electrode 34, and a negative current collector 35 that are sequentially stacked.

As shown in FIG. 11, the thin film transistor 20 of the AMOLED back plate of the present embodiment includes: a buffer layer 11 covering the substrate 10; a gate electrode 22 arranged on the buffer layer 11, in which the gate electrode 22 and the positive current collector 31 of the thin film battery 30 are arranged in a same layer and formed by a single patterning process; a first insulating layer 12 covering the gate electrode 22; an active layer 21 on the first insulating layer 12; a first electrode 23 and a second electrode 24 arranged on the first insulating layer 12, in which one end of the first electrode 23 is arranged on the active layer 21, one end of the second electrode 24 is arranged on the active layer 21, and a conductive channel of the thin film transistor is formed between the first electrode 23 and the second electrode 24; in which the first electrode 23 and the second electrode 24 as well as the negative current collector 35 of the thin film battery 30 are arranged in the same layer and formed by a single patterning process; a third insulating layer 14 covering the first electrode 23 and the second electrode 24, on which the fourth via hole exposing the first electrode 23 is provided.

In this embodiment, the material of the active layer 21 is a metal oxide such as IGZO or ITZO, the first electrode 23 is a drain electrode, and the second electrode 24 is a source electrode. In actual implementation, the buffer layer is not necessary, and may be provided according to the process requirements. The first electrode and the second electrode may also be the source electrode and the drain electrode, respectively.

As shown in FIG. 11, the thin film battery 30 of the AMOLED back plate of the present embodiment includes: a buffer layer 11 covering the substrate 10; a positive current collector 31 arranged on the buffer layer 11, in which a positive current collector 31 and the gate electrode 22 of the thin film transistor 20 are arranged in the same layer and formed by a single patterning process; a first insulating layer 12 covering the positive current collector 31, on which a third via hole exposing the positive current collector 31 is provided; a positive electrode 32 arranged on the positive current collector 31 in the third via hole; an electrolyte 33 arranged on the positive electrode 32; a negative electrode 34 arranged on the electrolyte 33; a negative current collector 35 arranged on the negative electrode 34, in which a negative current collector 35 as well as the first electrode 23 and the second electrode 24 of the thin film transistor 20 are arranged in the same layer and formed by a single patterning process; and a third insulating layer 14 covering the negative current collector 35.

In this embodiment, the thin film battery is preferably an all solid state thin film lithium battery.

As shown in FIG. 11, the light emitting structure layer 200 of the AMOLED back plate of this embodiment is the same as the light emitting structure layer of the foregoing first embodiment.

As shown in FIG. 11, the AMOLED back plate of the present embodiment includes: a substrate 10; a buffer layer 11 covering the substrate 10; a gate electrode 22 of the thin film transistor and a positive current collector 31 of the thin film battery formed on the buffer layer 11 by a single patterning process; a first insulating layer 12 covering the gate electrode 22 and the positive current collector 31, on which a third via hole exposing the positive current collector 31 is provided; an active layer 21 arranged on the first insulating layer 12, in which the active layer 21 is an oxide active layer; a positive electrode 32, an electrolyte 33, and a negative electrode 34 arranged in the third via hole; a first electrode 23 and a second electrode 24 of the thin film transistor arranged on the first insulating layer 12 as well as a negative current collector 35 of the thin film battery arranged on the negative electrode 34, in which the first electrode 23 and the second electrode 24 together with the negative current collector 35 are formed by a single patterning process, one end of the first electrode 23 is arranged on the active layer 21, one end of the second electrode 24 is arranged on the active layer 21, a conductive channel of the thin film transistor is formed between the first electrode 23 and the second electrode 24, and the negative current collector 35 is arranged on the negative electrode 34; a third insulating layer 14 covering the first electrode 23, the second electrode 24, and the negative current collector 35, on which a fourth via hole exposing the first electrode 23 is provided; an anode 41 arranged on the third insulating layer 14, in which the anode 41 is connected to the first electrode 23 of the thin film transistor 20 through the fourth via hole; a fourth insulating layer 15 covering the anode 41, on which a fifth via hole exposing the anode 41 is provided; a light emitting layer 42 arranged on the anode 41 in the fifth via hole; a cathode 43 arranged on the light-emitting layer 42; and a package layer 16 covering the cathode 43.

The technical solution of the embodiment of the present disclosure is further illustrated by the preparation process of the active matrix organic light emitting diode back plate.

First, patterns of the gate electrode and the positive current collector are formed. The step of forming patterns of the gate electrode and the positive current collector includes: sequentially depositing a buffer layer thin film and a first metal thin film on the substrate, patterning the first metal thin film by a patterning process, and forming a buffer layer 11 and patterns of a gate electrode 22 of the thin film transistor and a the positive current collector 31 of the thin film battery on the substrate 10, as shown in FIG. 12. In this process, the gate electrode of the thin film transistor and the positive current collector of the thin film battery are arranged in the same layer, and are formed by a single patterning process.

Subsequently, an pattern of the active layer is formed. The step of forming the pattern of the active layer includes: sequentially depositing a first insulating layer thin film and an active layer thin film on the substrate on which the foregoing patterns have been formed, performing a conducting process on the active layer thin film, then performing a patterning process on the conducted active layer thin film through a patterning process, to form a pattern of the first insulating layer 12 covering the gate electrode 22 and the positive current collector 31 and to form a pattern of the active layer 21 on the first insulating layer 12, as shown in FIG. 13. In this embodiment, the material of the active layer may be IGZO or ITZO.

Subsequently, a via hole is provided on the first insulating layer. The step of providing the via hole on the first insulating layer includes: coating a photoresist on the first insulating layer 12, exposing and developing the photoresist by using a monotone mask, forming a fully exposed region at a position of positive current collector 31, removing the photoresist, forming an unexposed region at other positions, and retaining the photoresist; etching the fully exposed region and stripping the remaining photoresist, forming a pattern of the third via hole K3 on the first insulating layer 12, in which the third via hole K3 is located at the position of the positive current collector 31, the first insulating layer 12 in the third via hole K3 being etched to expose the surface of the positive current collector 31, as shown in FIG. 14.

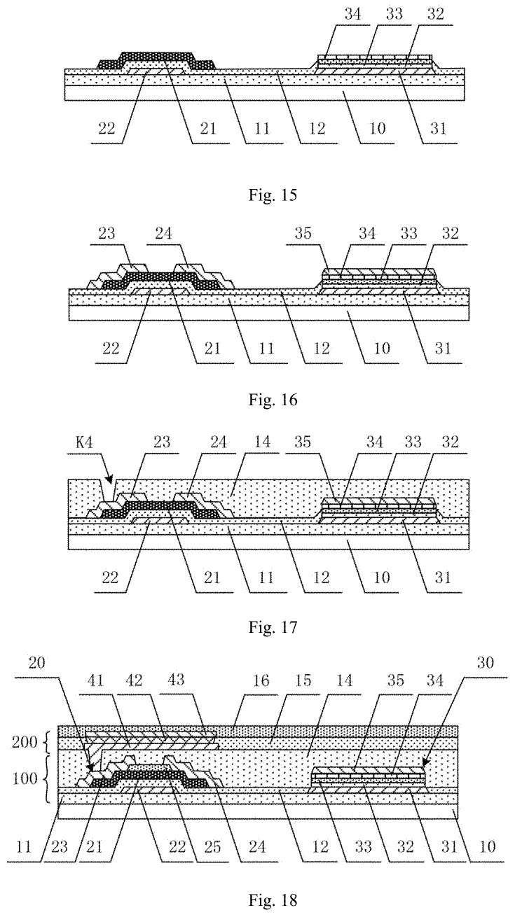

Subsequently, the step of forming patterns of the positive electrode, the electrolyte, and the negative electrode are identical in a manner and structure to be formed to that of forming patterns of the positive electrode, the electrolyte, and the negative electrode in the foregoing embodiment, as shown in FIG. 15.

Subsequently, patterns of the first electrode, the second electrode, and the negative current collector are formed. The step of forming patterns of the first electrode, the second electrode, and the negative current collector includes: depositing a second metal thin film on the substrate on which the foregoing patterns have been formed, patterning the second metal thin film by a patterning process, forming patterns of the first electrode 23 and the second electrode 24 of the thin film transistor on the first insulating layer 12, forming a pattern of the negative current collector 35 of the thin film battery on the negative electrode 34, in which one end of the first electrode 23 proximate to the second electrode 24 is arranged on the active layer 21, one end of the second electrode 24 proximate to the first electrode 23 is also arranged on the active layer 21, a conductive channel of the thin film transistor is formed between the first electrode 23 and the second electrode 24, and a negative current collector 35 is arranged on the negative electrode 34 as shown in FIG. 16. In this process, the first electrode and the second electrode of the thin film transistor as well as the negative current collector of the thin film battery are arranged in the same layer, and formed by a single patterning process.

Subsequently, a pattern of the third insulating layer with via holes is formed. The step of forming the third insulating layer pattern with via holes includes: coating a third insulating layer thin film on the substrate on which the foregoing patterns have been formed, and forming a pattern of the third insulating layer 14 with the fourth via hole K4 by patterning the third insulating layer thin film by a patterning process, in which the fourth via hole K4 is located at the position of the first electrode 23, and etching the third insulating layer 14 in the fourth via hole K4 to expose the surface of the first electrode 23, as shown in FIG. 17.

Subsequently, patterns of the anode, the pixel definition layer, the light emitting layer, and the cathode pattern are formed as shown in FIG. 11. The process for forming patterns of the anode, the pixel definition layer, the light emitting layer, and the cathode pattern is same as that of the foregoing embodiment.

In this embodiment, the materials used for the respective structural layers are same as those of the foregoing embodiments except for the active layer, and are not described herein again.

In the present embodiment, the gate electrode of the thin film transistor and the positive current collector of the thin film battery are arranged in the same layer and formed by a single patterning process, and the first electrode and the second electrode of the thin film transistor as well as the negative current collector of the thin film battery are arranged in the same layer and formed by a single patterning process, thus a simultaneous preparation of a thin film transistor and thin film battery that are coplanar can be achieved thereby. Since the thin film transistor and the thin film battery are of a coplanar structure, the active matrix organic light emitting diode back plate of the embodiment of the present disclosure maximizes integration and reduces the overall module thickness, as compared with the existing combined structure. Since the thin film transistor and the thin film battery are simultaneously prepared, the active matrix organic light emitting diode back plate of the embodiment of the present disclosure significantly reduces the number of patterning process, simplifies the preparation process, and reduces the production cost, as compared with the existing stacked structure.

FIG. 18 is a schematic view showing a structure of an AMOLED back plate according to a yet embodiment of the present disclosure, and this embodiment is an extending development of the previous embodiment. As shown in FIG. 18, in the embodiment, the main structure of the AMOLED back plate includes: a thin film transistor 20 and a thin film battery 30 that are coplanar and arranged on the substrate 10, and a light emitting structure layer 200 arranged on the thin film transistor 20 and the thin film battery 30. The light emitting structure layer 200 and the thin film battery 30 are same as those of previous embodiment. Unlike the previous embodiment, the thin film transistor 20 of the present embodiment is further provided with an etch stop layer.

Specifically, the thin film transistor 20 of the AMOLED back plate of the present embodiment includes: a buffer layer 11 covering the substrate 10; a gate electrode 22 arranged on the buffer layer 11, in which the gate electrode 22 and the positive current collector 31 of the thin film battery 30 are arranged in a same layer and formed by a single patterning process; a first insulating layer 12 covering the gate electrode 22; an active layer 21covering the first insulating layer 12; an etch stop layer 25 arranged on the active layer 21; a first electrode 23 and a second electrode 24 arranged on the first insulating layer 12, in which one end of the first electrode 23 is arranged on the etch stop layer 25, one end of the second electrode 24 is arranged on the etch stop layer 25, a conductive channel of the thin film transistor is formed between the first electrode 23 and the second electrode 24, and the first electrode 23 and the second electrode 24 as well as the negative current collector 35 of the thin film battery 30 are arranged in the same layer and formed by a single patterning process; a third insulating layer 14 covering the first electrode 23 and the second electrode 24, on which the third via hole exposing the first electrode 23 is provided.

The main process for preparing the active matrix OLED back plate is same as that of the previous embodiment, except that patterns of the active layer and the etch stop layer are formed by a halftone mask or a gray tone mask. The specific processing includes: after forming of patterns of the gate electrode and the positive current collector, sequentially depositing the first insulating layer thin film and the active layer thin film, performing a conducting process on the active layer thin film, and then depositing an etch stop layer thin film on the conducted active layer thin film; coating a layer of photoresist on the etch stop layer thin film, stepwise exposing and developing the photoresist by using a halftone mask or a gray tone mask, forming an unexposed region at a position of the etch stop layer with a photoresist of a first thickness, forming a partially exposed region at a position of the active layer with a photoresist of a second thickness less than the first thickness, forming a fully exposed region at other locations without photoresist, and exposing the etch stop layer thin film. The etch stop layer thin film and the active layer thin film of the fully exposed region are etched by the first etching, to form a pattern of the active layer pattern. Then, the photoresist is removed to the second thickness as a whole by a photoresist ashing process, that is, the photoresist in the partially exposed region is removed to expose the etch stop layer thin film of the partially exposed region. Then, the etch stop layer thin film exposed by the partially exposed regions is etched by a second etching, and the remaining photoresist is stripped to form an etch barrier pattern on the active layer pattern. In this embodiment, the etch stop layer is provided for avoiding the over etching of the channel region of the active layer in the subsequent patterning of the first electrode and the second electrode, to ensure the electrical performance of the thin film transistor.

This embodiment not only has the advantageous effects of the previous embodiment, but also ensures the electrical performance of the thin film transistor by providing an etch stop layer.

Although the foregoing first two embodiments have been described with a bottom gate structure, the present disclosure is also applicable to a top gate structure. For example, the top gate oxide type AMOLED back plate includes: a substrate, a light shielding layer formed on the substrate, a buffer layer covering the light shielding layer, an oxide active layer formed on the buffer layer, a gate insulating layer and a gate electrode formed on the oxide active layer, an interlayer dielectric layer covering the gate electrode, a source electrode and a drain electrode formed on the interlayer dielectric layer, and the planarization layer covering the source electrode and the drain electrode.

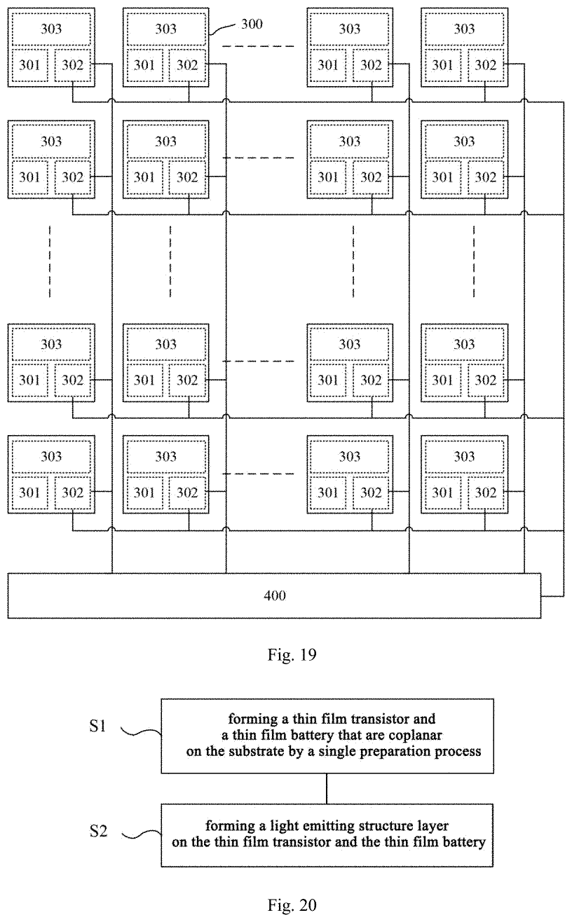

FIG. 19 is a schematic view showing a structure of an AMOLED back plate according to another embodiment of the present disclosure, which illustrates the technical solution of the present disclosure from the perspective of the planar structure of the AMOLED back plate. As shown in FIG. 19, the AMOLED back plate includes M*N pixel units 300 arranged in a matrix on a substrate, in which each of the pixel units 300 is provided with a driving unit 301, a battery unit 302, and a light emitting unit 303. The driving unit 301 is a pixel driving circuit, which is composed of a plurality of thin film transistors and capacitors, and used for driving the AMOLED back plate to achieve balanced and continuous illumination. Each of the thin film transistors adopts the thin film transistor structure of the foregoing embodiment, including a gate electrode, an active layer, a source electrode, and a drain electrode. The battery unit 302 may be an all solid state lithium battery, including a positive current collector, a positive electrode, an electrolyte, a negative electrode, and a positive current collector that are stacked in sequence. The light emitting unit 303 adopts the structure of the light emitting structure layer in the foregoing embodiment, including an anode, a light emitting layer, and a cathode. From the perspective of the pixel region, each pixel unit 300 can also be divided into a pixel control area, a display area, and a thin film battery area. The display area is a light emitting area arranged above the pixel control area (pixel driving circuit), and the thin film battery area is used for placing an all solid state lithium battery, to provide energy for the display of the AMOLED back plate.

In the AMOLED back plate of this embodiment, the pixel driving circuits in each pixel unit are electrically connected to each other, and the positive electrodes and the negative electrodes of all M*N all solid state lithium batteries are respectively connected together by wires arranged on the substrate, and are respectively connected to a flexible printed circuit (FPC) 400. Each of the all solid state lithium batteries is charged and discharged through the flexible circuit board 400. The AMOLED back plate is supplied with electric energy for display when the all solid state lithium battery is discharged, and is charged when the all solid state lithium battery consumes electric power to a certain extent.

Embodiments of the present disclosure also provide a method of preparing an active matrix organic light emitting diode back plate. FIG. 20 is a flow chart showing a method for preparing an active matrix organic light emitting diode back plate according to an embodiment of the present disclosure. As shown in FIG. 20, a method for preparing an active matrix organic light emitting diode back plate includes: S1, forming a thin film transistor and a thin film battery that are coplanar on a substrate by a single preparation process; and S2, forming a light emitting structure layer on the thin film transistor and the thin film battery.

The step S1 may include: forming a gate electrode of the thin film transistor and a positive current collector of the thin film battery by a single patterning process; and forming a first electrode and a second electrode of the thin film transistor as well as the negative current collector of the thin film battery by a single patterning process.

The thin film battery includes an all solid state thin film lithium battery.

In another embodiment, step Si includes: S111, forming a polysilicon active layer of the thin film transistor on a substrate; S112, forming a gate electrode of the thin film transistor and a positive current collector of the thin film battery by a single patterning process; S113, forming a positive electrode, an electrolyte, and a negative electrode of the thin film battery sequentially; and S114, forming a first electrode and a second electrode of the thin film transistor as well as a negative current collector of the thin film battery by a single patterning process.

Step S111 includes: sequentially depositing a buffer layer thin film and a polysilicon thin film on the substrate, coating a layer of photoresist on the polysilicon thin film, stepwise exposing and developing the photoresist by using a halftone mask or a gray tone mask, forming an unexposed region at a position of the channel region of the active layer with a photoresist of a first thickness, forming a partially exposed region at a position of the doped region of the active layer with a photoresist of a second thickness less than the first thickness, forming a fully exposed region at other locations without photoresist, and exposing the polysilicon thin film; etching the polysilicon thin film in the fully exposed region by the first etching; exposing the polysilicon thin film in the partially exposed region by the ashing process; P⁺ doping the polysilicon thin film exposed in the partially exposed region, stripping the remaining photoresist, and forming a buffer layer and a polysilicon active layer of the thin film transistor on the substrate, in which the polysilicon active layer includes a channel region in the middle and doped regions located on both sides of the channel region.

Step S112 includes: sequentially depositing a first insulating layer and a first metal thin film; forming a first insulating layer covering the polysilicon active layer as well as a gate electrode of the thin film transistor arranged on the first insulating layer and a positive current collector of the thin film battery by a patterning process.

Step S113 includes: forming a second insulating layer covering the gate electrode and the positive current collector by a patterning process; forming a first via hole, a second via hole, and a third via hole on the second insulating layer, in which the first via hole and the second via hole are located at a position where the doped region of the active layer is located, and the third via hole is located at a position where the positive current collector is located; and forming a positive electrode, an electrolyte, and a negative electrode of the thin film battery sequentially in the third via hole.

Step S114 includes: depositing a second metal thin film; forming a first electrode and a second electrode of the thin film transistor on the second insulating layer by a patterning process, and forming a negative current collector of the thin film battery on the negative electrode, in which the first electrode and the second electrode are respectively connected to the doped region of the active layer through the first via hole and the second via hole, and the negative current collector is formed on the negative electrode.

In another embodiment, step Si includes: S121, forming a gate electrode of the thin film transistor and a positive current collector of the thin film battery by a single patterning process on the substrate; S122, forming an oxide active layer of the thin film transistor; S123, forming a positive electrode, an electrolyte, and a negative electrode of the thin film battery sequentially; and S124, forming a first electrode and a second electrode of the thin film transistor as well as a negative current collector of the thin film battery by a single patterning process.

Step S121 includes: sequentially depositing a buffer layer thin film and a first metal thin film on the substrate; forming a buffer layer as well as a gate electrode of the thin film transistor and a positive current collector of the thin film battery arranged on the buffer layer by a patterning process.

Step S122 includes: depositing a first insulating layer thin film and an active layer thin film sequentially; and forming a first insulating layer covering the gate electrode and the positive current collector as well as an oxide active layer arranged on the first insulating layer by a patterning process.

Step S123 includes: forming a third via hole on the first insulating layer by a patterning process, the third via hole being located at a position where the positive current collector is located; and forming a positive electrode, an electrolyte, and a negative electrode of the thin film battery sequentially in the third via hole.

Step S124 includes: depositing a second metal thin film; forming a first electrode and a second electrode of the thin film transistor on the first insulating layer and forming a negative current collector of the thin film battery on the negative electrode by a patterning process, in which one end of the first electrode is connected to the oxide active layer, one end of the second electrode is connected to the oxide active layer, a conductive channel of the thin film transistor is formed between the first electrode and the second electrode, and the negative current collector is formed on the negative electrode.

Step S2 includes: S21, forming a third insulating layer with a fourth via hole, in which the fourth via hole is located at a position of the first electrode; S22, depositing a transparent conductive thin film, and forming an anode of the light emitting structure layer on the third insulating layer through a patterning process, in which the anode is connected to the first electrode through the fourth via hole; S23, forming a fourth insulating layer with a fifth via hole, in which the fifth via hole is located at a position of the anode; S24, sequentially forming a light emitting layer and a cathode in the fifth via hole; and S25, forming an package layer.

The specific process for preparing the active matrix organic light emitting diode back plate has been described in detail in the process for preparing the active matrix organic light emitting diode back plate of the foregoing embodiment, and will not be described herein.

In the method for preparing the active matrix organic light emitting diode back plate provided by the embodiment of the present disclosure, the gate electrode of the thin film transistor and the positive current collector of the thin film battery are formed by a single patterning process, and the first electrode and the second electrode of the thin film transistor as well as the negative current collector of the thin film battery are formed by a single patterning process, thus a simultaneous preparation of a thin film transistor and thin film battery that are coplanar can be achieved thereby. The embodiment significantly reduces the number of patterning process, simplifies the preparation process, and reduces the production cost, as compared with the existing preparation method. At the same time, the prepared active matrix organic light emitting diode back plate maximizes integration and reduces the overall module thickness.

The embodiment of the present disclosure further provides a display panel, including the AMOLED back plate of the foregoing embodiment. The display panel may be a mobile phone, a tablet computer, a television, a display, a notebook computer, a digital photo frame, a navigator, or any product or component having a display function. Since the display panel includes any of the above AMOLED back plates, the same technical problem can be solved and the same technical effects are obtained, which will not be described herein.

In the description of the present invention, it should be noted that the terms “middle”, “up”, “down”, “front”, “back”, “vertical”, “horizontal”, “top”, “bottom”, “inside”, “outside”, etc. indicating the orientation or spatial relationship is based on the orientation or spatial relationship shown in the drawings, and are merely for the convenience of describing the present invention and the simplification of the description, rather than indicating or implying that the referred device or element must have a particular orientation, or be constructed and operated in a particular orientation. Thus, it should not be construed as a limitation on the present invention.

In the description of the embodiments of the present disclosure, it should be understood that “thin film” refers to a layer of thin film formed of some material on a substrate by deposition or other processes. If the “thin film” does not require a patterning process throughout the manufacturing process, the “thin film” may also be referred to as “layer”; and if the “thin film” requires a patterning process throughout the manufacturing process, it is referred to as “thin film” before the patterning process, and referred to as “layer” after the patterning process. The “layer” after the patterning process contains at least one “pattern”.

In the description of the embodiment of the present disclosure, it should be noted that, unless expressly stated or limited otherwise, the terms “mount”, “connect” or “join” shall be interpreted broadly, and may be, for example, fixed connection, removable connection, or integral connection; may be a mechanical connection, may also be an electrical connection; may be direct connection, or may be indirect connection through an intermediary medium, and may be the internal communication of two components. The specific meanings of the above terms in the present disclosure can be understood by a person skilled in the art on the specific basis.

The embodiments disclosed in the present disclosure are as described above, but they are merely used to facilitate the understanding of the embodiments of the present disclosure, and are not intended to limit the embodiments of the present disclosure. Any modification and variation in the form and details of the present disclosure may be made by one skilled in the art without departing from the spirit and scope of the present disclosure. The scope of patent protection is still subject to the scope defined by the appended claims.

1. An active matrix organic light emitting diode back plate, comprising:
a substrate;
a thin film transistor and a thin film battery that are coplanar and located on the substrate; and
a light emitting structure layer located on the thin film transistor and the thin film battery.

2. The active matrix organic light emitting diode back plate of claim 1, wherein a gate electrode of the thin film transistor as well as a positive current collector of the thin film battery are arranged in a same layer.

3. The active matrix organic light emitting diode back plate of claim 1, wherein a first electrode and a second electrode of the thin film transistor as well as a negative current collector of the thin film battery are arranged in a same layer.

4. (canceled)

5. The active matrix organic light emitting diode back plate of claim 1, wherein the thin film transistor comprises:
a polysilicon active layer on the substrate;
a first insulating layer covering the polysilicon active layer;
a gate electrode located on the first insulating layer;
a second insulating layer covering the gate electrode, and comprising a first via hole and a second via hole that expose the polysilicon active layer;
a first electrode and a second electrode that are located on the second insulating layer, wherein the first electrode and the second electrode are respectively connected to the polysilicon active layer through the first via hole and the second via hole; and
a third insulating layer covering the first electrode and the second electrode, comprising a fourth via hole that exposes the first electrode.

6. The active matrix organic light emitting diode back plate of claim 1, wherein the thin film transistor comprises:
a gate electrode located on the substrate;
a first insulating layer covering the gate electrode;
an oxide active layer located on the first insulating layer;
a first electrode and a second electrode that are located on the first insulating layer, wherein one end of the first electrode is connected to the oxide active layer, one end of the second electrode is connected to the oxide active layer, and a conductive channel is formed between the first electrode and the second electrode; and
a third insulating layer covering the first electrode and the second electrode, comprising a fourth via hole that exposes the first electrode.

7. The active matrix organic light emitting diode back plate of claim 6, wherein an etch stop layer is further arranged on the oxide active layer.

8. The active matrix organic light emitting diode back plate of claim 1, wherein the thin film battery comprises a positive current collector, a positive electrode, an electrolyte, a negative electrode, and a negative current collector that are sequentially stacked.

9. A display panel, comprising the active matrix organic light emitting diode back plate of claim 1.

10. A method for preparing an active matrix organic light emitting diode back plate, comprising:
forming a thin film transistor and a thin film battery that are coplanar on the substrate by a single preparation process; and
forming a light emitting structure layer on the thin film transistor and the thin film battery.

11. The method of claim 10, wherein the step of forming the thin film transistor and the thin film battery that are coplanar on the substrate by the single preparation process comprises:
forming a gate electrode of the thin film transistor and a positive current collector of the thin film battery by the single patterning process.

12. The method of claim 10 or 11, wherein the step of forming the thin film transistor and the thin film battery that are coplanar on the substrate by the single preparation process comprises:
forming a first electrode and a second electrode of the thin film transistor as well as a negative current collector of the thin film battery by the single patterning process.

13. (canceled)

14. The method of claim 10, wherein the step of forming the thin film transistor and the thin film battery that are coplanar on the substrate by the single preparation process comprises:
forming a polysilicon active layer of the thin film transistor on the substrate;
forming a gate electrode of the thin film transistor and a positive current collector of the thin film battery by the single patterning process;
forming a positive electrode, an electrolyte, and a negative electrode of the thin film battery sequentially; and
forming a first electrode and a second electrode of the thin film transistor as well as a negative current collector of the thin film battery by the single patterning process.

15. The method of claim 14, wherein the step of forming the gate electrode of the thin film transistor and the positive current collector of the thin film battery by the single patterning process comprises:
depositing a first insulating layer and a first metal thin film sequentially; and
forming a first insulating layer covering the polysilicon active layer as well as a gate electrode of the thin film transistor located on the first insulating layer and a positive current collector of the thin film battery by a patterning process.

16. The method of claim 15, wherein the step of forming the positive electrode, the electrolyte and the negative electrode of the thin film battery sequentially comprises:
forming a second insulating layer covering the gate electrode and the positive current collector by a patterning process;
forming a first via hole, a second via hole, and a third via hole on the second insulating layer, in which the first via hole and the second via hole are each located at a position where the polysilicon active layer is located, and the third via hole is located at a position where the positive current collector is located; and
forming a positive electrode, an electrolyte, and a negative electrode of the thin film battery sequentially in the third via hole.

17. The method of claim 16, wherein the step of forming the first electrode and the second electrode of the thin film transistor as well as the negative current collector of the thin film battery by the single patterning process comprises:
depositing a second metal thin film; and
forming a first electrode and a second electrode of the thin film transistor as well as a negative current collector of the thin film battery by a patterning process, wherein the first electrode and the second electrode are respectively connected to the polysilicon active layer through the first via hole and the second via hole, and the negative current collector is formed on the negative electrode.

18. The method of claim 10, wherein the step of forming the thin film transistor and the thin film battery that are coplanar on the substrate by the single preparation process comprises:
forming a gate electrode of the thin film transistor and a positive current collector of the thin film battery by the single patterning process on the substrate;
forming an oxide active layer of the thin film transistor;
forming a positive electrode, an electrolyte, and a negative electrode of the thin film battery sequentially; and
forming a first electrode and a second electrode of the thin film transistor as well as a negative current collector of the thin film battery by the single patterning process.

19. The method of claim 18, wherein the step of forming the gate electrode of the thin film transistor and the positive current collector of the thin film battery by the single patterning process on the substrate comprises:
depositing a first metal thin film on the substrate; and
forming a gate electrode of the thin film transistor and a positive current collector of the thin film battery by a patterning process.

20. The method of claim 19, wherein the step of forming the oxide active layer of the thin film transistor comprises:
depositing a first insulating layer thin film and an active layer thin film sequentially; and
forming a first insulating layer covering the gate electrode and the positive current collector as well as an oxide active layer located on the first insulating layer by a patterning process.

21. The method of claim 20, wherein the step of forming the positive electrode, the electrolyte and the negative electrode of the thin film battery sequentially comprises:
forming a third via hole on the first insulating layer by a patterning process, wherein the third via hole is located at a position where the positive current collector is located; and
forming a positive electrode, an electrolyte, and a negative electrode of the thin film battery sequentially in the third via hole.

22. The method of claim 21, wherein the step of forming the first electrode and the second electrode of the thin film transistor as well as the negative current collector of the thin film battery by the single patterning process comprises:
depositing a second metal thin film; and
forming a first electrode and a second electrode of the thin film transistor as well as a negative current collector of the thin film battery by a patterning process, wherein one end of the first electrode is connected to the oxide active layer, one end of the second electrode is connected to the oxide active layer, a conductive channel of the thin film transistor is formed between the first electrode and the second electrode, and the negative current collector is formed on the negative electrode.
